(19) United States
(12) Patent Application Publication
(10) Pub. No.: US 2025/0286559 A1
(43) Pub. Date: Sep. 11, 2025

(54) METHOD AND DEVICE FOR SETTING A SYSTEM CLOCK OF AN INTEGRATED CIRCUIT

(71) Applicant: Robert Bosch GmbH, Stuttgart (DE)

(72) Inventors: Christoph Puttmann, Kusterdingen (DE); Julian Schwarz, Tuebingen (DE)

(21) Appl. No.: 19/061,628

(22) Filed: Feb. 24, 2025

(30) Foreign Application Priority Data
Mar. 5, 2024 (DE) 10 2024 202 016.8

(51) Int. Cl. H03L 7/099; H03L 7/199

(52) U.S. Cl. CPC H03L 7/0992; H03L 7/199

(57) ABSTRACT

A method for setting a system clock of an integrated circuit. The integrated circuit has an oscillator module which specifies a system clock of the integrated circuit, a counter module, a signal input, and a communication interface. The method includes: receiving a reference signal at the signal input for a predefined duration; incrementing the counter module by one per system clock of the integrated circuit over the duration of the application of the reference signal; ascertaining a counter value of the counter module after expiration of the duration; receiving a counter target value at the communication interface, which counter target value corresponds to a number of system clocks at a target frequency during the duration; comparing the counter value of the counter module with the counter target value and correcting a frequency of the oscillator module based on a deviation of the counter value from the counter target value.

### BACKGROUND INFORMATION

Embedded oscillators in application-specific integrated circuits (ASICs) are conventional and are used in a variety of applications in many areas. Furthermore, it can be generally stated that today's ASICs mostly contain function blocks for counting certain events (counter module).

In order to compensate for production-related process variations, a method for calibrating the desired target frequency (oscillator trimming) is often performed after ASIC production. For performing this frequency calibration, part-specific frequency measurements are at present usually performed with external test devices, which are time-consuming and therefore costly.

Typically, for calibrating the frequency of an embedded oscillator, the clock signal is connected via an output pin of the ASIC to an external test device, which performs a frequency measurement. On the basis of the measurement result, the configuration of the embedded oscillator is then changed such that the measured frequency deviates as little as possible from the desired target frequency. This is an iterative method that requires multiple frequency measurements and configuration changes.

### SUMMARY

The method according to the present invention can be performed in a short time and is cost-effective. In particular, a very simple test device is used, which is connected to an integrated circuit. In addition, no complicated calculations are necessary, and therefore the method is resource-saving.

The method of the present invention is used to set a system clock of an integrated circuit. The integrated circuit has an oscillator module designed to specify a system clock of the integrated circuit, a counter module, a signal input, and a communication interface. A frequency can be set for the oscillator module, wherein the method is used to set the frequency to a desired value. The frequency of the oscillator module then determines the system clock during operation of the integrated circuit. The counter module is preferably an event counter. In the simplest case, the counter module can count the number of system clocks over a certain period of time.

According to an example embodiment of the present invention, the method comprises the following steps: First, a step a) of receiving a reference signal at the signal input for a predefined duration is carried out. In addition, a step b) of incrementing the counter module by one per system clock of the integrated circuit is carried out over the duration of the application of the reference signal. The counter module thus counts the number of system clocks as long as the reference signal is applied. Knowing the duration for which the reference signal is applied, the counter module can thus be used to deduce the actual system clock.

According to an example embodiment of the present invention, a step c) of ascertaining a counter value of the counter module is carried out after expiration of the duration. In addition, a step d) of receiving a counter target value at the communication interface is carried out. In particular, the counter target value is generated by an external device, wherein the counter target value corresponds to a number of system clocks at a target frequency during the duration. In other words, the external device advantageously generates the reference signal and determines the number of system clocks that should occur during the duration of the reference signal. This corresponds to a system clock specification, wherein the system clock specification is to be set for the integrated circuit.

Therefore, according to an example embodiment of the present invention, a step e) of comparing the counter value of the counter module with the counter target value and correcting a frequency of the oscillator module based on a deviation of the counter value from the counter target value is carried out. If the frequency of the oscillator module matches the specified target frequency, then the system clock of the integrated circuit has the desired value. If this is not the case, this can be recognized in that the counter module does not count the correct number of system clocks during the duration of the reference signal. The frequency of the oscillator module is then either too high, as a result of which the system clock is too fast and the counter module has a higher counter value than the counter target value. Alternatively, the frequency of the oscillator module is too low, as a result of which the system clock is too slow and the counter module has a lower counter value than the counter target value. In both cases, the faulty frequency is detectable and correctable.

The method of the present invention does not require any complex external systems; only the reference signal and the counter target value must be provided. Setting the system clock is mainly carried out by on-board means of the integrated circuit, such as in particular the counter module. Complex or time-consuming calculations are avoided. The method can be performed quickly and at low cost.

Preferred developments of the present invention are disclosed herein.

According to an example embodiment of the present invention preferably, after step e) of comparing and correcting, the counter reading of the counter module is reset. Then, all steps a) to e) are repeated in order to iteratively correct the frequency of the oscillator module. In this way, the frequency of the oscillator module can be precisely set in order to adapt the system clock of the integrated circuit to a specification as best as possible.

According to an example embodiment of the present invention, particularly advantageously, the duration of the reference signal during each repetition of steps a) to e) is longer than during previously performed repetitions of these steps. In this way, short durations of the reference signal can be used, in particular during the first repetitions, during which a rough adjustment can be made, with longer durations being provided in the further course. The total time for setting the system clock is thus minimized.

According to an example embodiment of the present invention, alternatively, it is preferably provided that the duration is the same for all repetitions. In this case, it is in particular not necessary to perform step d) of receiving the counter target value multiple times in each repetition of steps a) to e) since the counter target value is always the same. Thus, step d) is carried out only once and not repeatedly. The individual iterations can be better compared in this way. In particular, the repetition that leads to the smallest deviation between the counter target value and the counter value can be stored as the final result.

The frequency of the oscillator module can advantageously be set by a binary value with N bits. This is common, for example, in application-specific integrated circuits (ASICs). N stands for a natural number. The iterative correction of the frequency is preferably started with a value in the middle of the value range that can be represented by the N bits, and is particularly advantageously adjusted more finely with each iteration.

In a particularly preferred embodiment of the present invention, the following steps are carried out in order to set the system clock of the integrated circuit: First, a step f) of using the highest value bit as the bit to be set is carried out. Then, a step g) of setting the bit to be set to 1 is carried out. Preferably, all other bits of the N bits, i.e., all bits except the highest value bit, are set to 0. In this way, a value in the middle of the number range that can be represented by the N bits is preferably set. As step h), the previously described steps a) to e) are performed, wherein, in step e), the bit to be set is set to 0 if the counter target value is less than the counter value, and is left at 1 if the counter target value is greater than or equal to the counter value. Thereafter, a step i) of using the next lower bit as the bit to be set is carried out. Finally, steps g) to i) are repeated until all N bits have been processed. Thus, starting with the highest value bit, all bits are set one after the other until the lowest value bit is set. In each repetition of steps a) to e), only the bit to be set is changed. All other bits, in particular all higher value bits, remain unchanged, which is particularly advantageous. This results in the frequency of the oscillator module being set iteratively in order to set the system clock of the integrated circuit. By using an iterative approach starting with the highest value bit, the setting is initially rough and then becomes finer with each lower value bit.

The present invention also relates to an integrated circuit. According to an example embodiment of the present invention, the integrated circuit has an oscillator module designed to specify a system clock of the integrated circuit, a counter module, a signal input, and a communication interface. A frequency can be set for the oscillator module, wherein the frequency is be set to a desired value. The frequency of the oscillator module then determines the system clock during operation of the integrated circuit. The counter module is preferably an event counter. In the simplest case, the counter module can count the number of system clocks over a certain period of time.

Particularly advantageously, the integrated circuit of the present invention is designed to carry out a method of the present invention as described above. In particular, the integrated circuit is designed to carry out the steps explained below. The integrated circuit is designed to first perform a step a) of receiving a reference signal at the signal input for a predefined duration. In addition, the integrated circuit is configured to perform a step b) of incrementing the counter module by one per system clock of the integrated circuit over the duration of the application of the reference signal. The counter module thus counts the number of system clocks as long as the reference signal is applied. Knowing the duration for which the reference signal is applied, the counter module can thus be used to deduce the actual system clock.

Furthermore, the integrated circuit is designed to carry out a step c) of ascertaining a counter value of the counter module after expiration of the duration. In addition, the integrated circuit is designed to carry out a step d) of receiving a counter target value at the communication interface. In particular, the counter target value is generated by an external device, wherein the counter target value corresponds to a number of system clocks at a target frequency during the duration. In other words, the external device advantageously generates the reference signal and determines the number of system clocks that should occur during the duration of the reference signal. This corresponds to a system clock specification, wherein the system clock specification is to be set for the integrated circuit.

Therefore, the integrated circuit is designed to perform a step e) of comparing the counter value of the counter module with the counter target value and correcting a frequency of the oscillator module based on a deviation of the counter value from the counter target value. If the frequency of the oscillator module matches the specified target frequency, then the system clock of the integrated circuit has the desired value. If this is not the case, this can be recognized in that the counter module does not count the correct number of system clocks during the duration of the reference signal. The frequency of the oscillator module is then either too high, as a result of which the system clock is too fast and the counter module has a higher counter value than the counter target value. Alternatively, the frequency of the oscillator module is too low, as a result of which the system clock is too slow and the counter module has a lower counter value than the counter target value. In both cases, the faulty frequency is detectable and correctable.

Preferably, the integrated circuit is designed to reset the counter reading of the counter module after step e) of comparing and correcting. In addition, the integrated circuit is preferably designed to thereafter repeat all steps a) to e) in order to iteratively correct the frequency of the oscillator module. In this way, the frequency of the oscillator module can be precisely set in order to adapt the system clock of the integrated circuit to a specification as best as possible.

The frequency of the oscillator module can advantageously be set by a binary value with N bits. This is common, for example, in application-specific integrated circuits (ASICs). N stands for a natural number. The integrated circuit is preferably designed to start the iterative correction of the frequency with a value in the middle of the value range that can be represented by the N bits. Particularly advantageously, the integrated circuit is designed to adjust the frequency more finely with each iteration.

The integrated circuit particularly preferably comprises a calibration module. The calibration module is designed to perform steps a) to e). In particular, a calibration algorithm for performing the method described above is implemented on the calibration module.

### BRIEF DESCRIPTION OF THE DRAWINGS

In the following, exemplary embodiments of the present invention are described in detail with reference to the figures.

FIG. 1 is a schematic view of an integrated circuit according to an exemplary embodiment of the present invention.

FIG. 2 is a schematic representation of a time sequence of signals of the integrated circuit according to an exemplary embodiment of the present invention.

FIG. 3 is a schematic representation of a sequence of setting a system clock of the integrated circuit according to the exemplary embodiment of the present invention.

### DETAILED DESCRIPTION OF EXAMPLE EMBODIMENTS

Preferably, identical components, elements, and/or units are provided with identical reference signs in all figures.

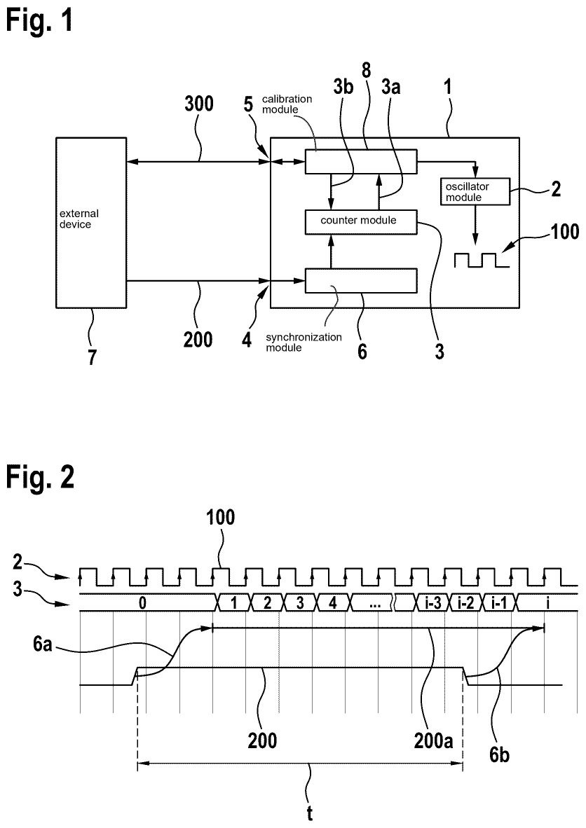

FIG. 1 schematically shows an integrated circuit 1 according to an exemplary embodiment of the present invention. The integrated circuit is in particular an application-specific integrated circuit, abbreviated ASIC.

The integrated circuit 1 comprises an oscillator module 2. The oscillator module 2 is designed to specify a system clock 100 of the integrated circuit 1. In addition, the integrated circuit 1 has a counter module 3, a signal input 4, and a communication interface 5. Furthermore, a calibration module 8 is provided, which is coupled in particular to the communication interface 5.

An external device 7 can be connected to the communication interface 5 in order to be able to establish a communication connection 300 with the calibration module 8. In addition, the external device 7 can be connected to the signal input 4 in order to output a reference signal 100 to the integrated circuit 1.

The signal input 4 is coupled to a synchronization module 6, wherein the synchronization module 6 is designed to synchronize the reference signal 200 with the system clock 100. The resulting synchronized reference signal 200a is output to the counter module 3 and is used to start and stop the counter module 3. When the level of the synchronized reference signal 100a corresponds to logic one, the value of the counter module 3 is incremented by one with each rising edge of the system clock. The calibration module 8 is coupled to the counter module 3 and allows a counter value 3a of the counter module 3 to be queried as well as reset 3b of the counter module 1. In addition, the calibration module 8 is designed to set a frequency of the oscillator module 2. For this purpose, a calibration algorithm is preferably implemented on the calibration module 8.

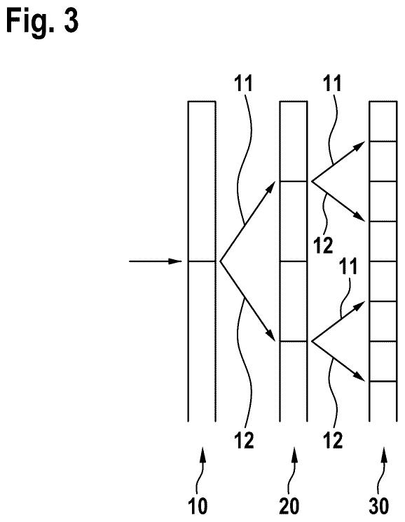

The frequency of the oscillator module 2 can be set by a binary value with N bits. N is a natural number. An iterative approach is used to set the frequency, as shown schematically in FIG. 3. For this purpose, a plurality of iterations 10, 20, 30 are performed, each with the same steps.

The iterative correction of the frequency of the oscillator module 2 starts with a value of the frequency in the middle of the value range that can be represented by the N bits. The calibration algorithm is designed to perform the following steps:

First, the highest value bit of the N bits is considered as the bit to be set. Each iteration 10, 20, 30 starts by setting the bit to be set to 1. All lower value bits are preferably set to the value 0 or left at this value. In the first iteration 10, a median of the number range that can be represented by the N bits is thus used by setting the highest value bit to 1. The number range that can be represented is shown schematically as a column in FIG. 3.

Thereafter, the calibration algorithm performs a plurality of steps to calibrate the set frequency to a desired frequency. At the signal input 4, a reference signal 100 is received from the external device 7 for a duration t. This means that the reference signal 200 represents logic 1 for the duration t. As explained above, this starts the counter module 3 so that the counter module 3 is incremented by one per system clock of the integrated circuit over the duration t of the application of the reference signal 200. After expiration of the duration t, the counter value 3a of the counter module 3 is ascertained by the calibration algorithm. In addition, the calibration module 8 receives a counter target value from the external device 7 via the communication interface 5, which counter target value corresponds to a number of system clocks at a desired target frequency during the duration t. By comparing the counter value 3a of the counter module 3 with the counter target value, a deviation of the frequency of the oscillator module 2 can be ascertained. The calibration algorithm corrects the frequency of the oscillator module 2 based on the deviation of the counter value 3a from the counter target value.

The frequency calibration is based on the principle that the counter module 3 is influenced over the duration t for which the external reference signal 200 is applied, i.e., the level corresponds to logic one, wherein a counter value 3a of the counter module 3 correlates directly with the frequency of the oscillator via the system clock. Using the signal form of the reference signal 100 specified by the external device 7 as well as the desired target frequency f to be set for the oscillator module 2, the counter target value of the counter module 3 can be calculated as follows: counter target value=t*f.

If the counter target value is less than the counter value 3a, the bit to be set is set to 0. In this case, the frequency of the oscillator module 2 is too high and the system clock 100 is too fast, which is why too many incrementations of the counter module 3 are carried out over the duration t. A reduction 12 is carried out. On the other hand, the value of the bit to be set is left at 1 if the counter target value is greater than or equal to the counter value 3a. In this case, the frequency of the oscillator module 2 is too low and the system clock 100 is too slow. Therefore, too few incrementations of the counter module 3 are carried out over the duration t. An increase 11 is carried out.

This completes the corresponding iteration 10, 20, 30. The next lower bit is then used as the bit to be set, and the above steps are repeated for the new bit to be set. This results in an increasingly finer adjustment of the frequency of oscillator module 2 until all N bits are set.

According to an example embodiment of the present invention, the duration (t) is the same for all repetitions, the counter target value is received only once and is not repeated.

The calibration algorithm allows the following options:
Since the oscillator configuration is initially set roughly with the highest value bit and then more precisely with each iteration 10, 20, 30, the duration t of the reference signal 200 can also be chosen to be short at the beginning and longer with each iteration 10, 20, 30. This results in a new counter target value for the counter value with each iteration 10, 20, 30, which new counter target value is to be transmitted via the communication interface 5. The total testing time can thus be reduced further.
Alternatively, the duration t of the reference signal 100 is chosen to be the same for each iteration 10, 20, 30. Therefore, the counter target value for the counter value is always the same and only needs to be transmitted once via the communication interface 5. This also makes the iterations 10, 20, 30 comparable. The calibration algorithm can therefore store the oscillator configuration that leads to the smallest deviation between the counter value 3a and the counter target value and can provide it as the final result after completion of the iterations 10, 20, 30.

The task of the external device is limited to providing the reference signal 200 and the counter target value. A part-specific calculation or configuration is not required. The individual calibration of the oscillator module 2 is performed by the integrated circuit 1 itself. As a result, the same stimulus from the external device 7 can be used to calibrate any number of integrated circuits 1 simultaneously.

The calibration of the oscillator frequency within the integrated circuit 1, in particular within the ASIC, with the aid of the counter module 3 and an external time reference can be performed much faster than via an otherwise common iterative frequency measurement on an external test device.

Furthermore, this invention makes it possible to simultaneously calibrate the frequency of multiple ASICs, since the external device 7 does not require an individual measuring channel to an ASIC. By carrying out the calibration algorithm within the ASIC, any number of components can be calibrated in parallel with the aid of a single external time reference. The resulting saving in testing time makes it possible to directly reduce the testing costs.

The additional logic that has to be implemented on the ASIC is of hardly any consequence; in particular, an already integrated counter module 3 can be reused.

1-10. (canceled)

11. A method for setting a system clock of an integrated circuit, wherein the integrated circuit includes an oscillator module configured to specify a system clock of the integrated circuit, a counter module, a signal input, and a communication interface, the method comprising the following steps:
a) receiving a reference signal at the signal input for a predefined duration;
b) incrementing the counter module by one per system clock of the integrated circuit over the duration of the receiving of the reference signal;
c) ascertaining a counter value of the counter module after expiration of the duration;
d) receiving a counter target value at the communication interface, the counter target value corresponding to a number of system clocks at a target frequency during the duration; and
e) comparing the counter value of the counter module with the counter target value and correcting a frequency of the oscillator module based on a deviation of the counter value from the counter target value.

12. The method according to claim 11, wherein, after step e) of comparing and correcting, a counter reading of the counter module is reset, wherein all steps a) through e) are repeated in order to iteratively correct the frequency of the oscillator module.

13. The method according to claim 12, wherein the duration of the reference signal is longer in each repetition of steps a) through e) than in previously performed repetitions of steps a) through e).

14. The method according to claim 12, wherein the duration is the same for all repetitions, wherein step d) of receiving the counter target value is carried out only once and is not repeated.

15. The method according to claim 12, wherein the frequency of the oscillator module can be set by a binary value with N bits, where Nis a natural number, and the iterative correction of the frequency is started with a value in a middle of a value range that can be represented by the N bits.

16. The method according claim 15, further comprising:
f) using a highest value bit as a bit to be set,
g) setting the bit to be set to 1,
h) performing steps a) to e), wherein, in step e), the bit to be set is set to 0 when the counter target value is less than the counter value, and is left at 1 when the counter target value is greater than or equal to the counter value,
i) using a next lower bit as the bit to be set, and
j) repeating steps g) to i) until all N bits have been processed.

17. An integrated circuit, comprising:
an oscillator module configured to specify a system clock of the integrated circuit;
a counter module;
a signal input; and
a communication interface;
wherein the integrated circuit is configured for the following tesp:
a) receiving a reference signal at the signal input for a predefined duration,
b) incrementing the counter module by one per system clock of the integrated circuit over the duration of the receiving of the reference signal,
c) ascertaining a counter value of the counter module after expiration of the duration,
d) receiving a counter target value at the communication interface, the counter target value corresponding to a number of system clocks at a target frequency during the duration, and
e) comparing the counter value of the counter module with the counter target value and correcting a frequency of the oscillator module based on a deviation of the counter value from the counter target value.

18. The integrated circuit according to claim 17, wherein the integrated circuit is configured to, after step e), reset a counter reading of the counter module and to repeatedly carry out all steps a) to e) to iteratively correct the frequency of the oscillator module.

19. The integrated circuit according to claim 18, wherein the frequency of the oscillator module can be set by a binary value with N bits, where N is a natural number, and wherein the integrated circuit is configured to start the iterative correction of the frequency with a value in a middle of a value range that can be represented by the N bits.

20. The integrated circuit according to claim 17, wherein a calibration module is configured to perform steps a) to e).
